(19) United States
(12) Patent Application Publication
(10) Pub. No.: US 2026/0312366 A1
(43) Pub. Date: Oct. 8, 2026

(54) MULTI-WAVELENGTH TUNABLE LASER

(71) Applicant: Lumentum Operations LLC, San Jose, CA (US)

(72) Inventors: Jiann-Chang LO, Cupertino, CA (US); Jia Ming Vinson MAR, San Ramon, CA (US); Shaoyi XIE, San Jose, CA (US); Paul LUDWIG, Livermore, CA (US)

(21) Appl. No.: 19/324,828

(22) Filed: Sep. 10, 2025

Related U.S. Application Data
(60) Provisional application No. 63/785,447, filed on Apr. 8, 2025.

(51) Int. Cl. H01S 5/10; H01S 5/00; H01S 5/024; H01S 5/06; H01S 5/14

(52) U.S. Cl. CPC H01S 5/1096; H01S 5/0064; H01S 5/02415; H01S 5/0612; H01S 5/141

(57) ABSTRACT

In some implementations a laser system may include a gain chip, a tunable wavelength selection component, and a bandpass component. The gain chip, within a cavity of the laser system, may be configured to emit a light beam. The tunable wavelength selection component, within the cavity, may be configured to filter the light beam into a first plurality of tunable transmission channels separated by a free spectral range. The bandpass component, within the cavity, may be configured to define a spectral bandpass that enables a second plurality of tunable transmission channels that form a multi-channel light beam for output from the cavity, where the second plurality of tunable transmission channels may be a subset of the first plurality of tunable transmission channels that falls within the spectral bandpass

### CROSS-REFERENCE TO RELATED APPLICATION

This Patent Application claims priority to US Patent Application No. 63/785,447, filed on Apr. 8, 2025, and entitled “MULTI-WAVELENGTH TUNABLE LASER.” The disclosure of the prior Application is considered part of and is incorporated by reference into this Patent Application.

### TECHNICAL FIELD

The present disclosure relates generally to optical lasers and to multi-wavelength tunable lasers.

### BACKGROUND

An external-cavity laser (ECL) is a type of laser system characterized by a resonator design, in which a portion of an optical cavity is situated outside a gain medium, where the gain medium may be a semiconductor diode. In some ECL setups, a laser diode emits light that exits a facet of the gain medium and travels through free space or other optical components before being reflected back into the diode by an external mirror or wavelength-selective element. An external cavity of the ECL plays a role in determining the laser's optical properties. By adjusting a position or an angle of the external cavity, users can finely tune the lasing wavelength over a broad spectral range. ECLs may also exhibit narrow linewidths, such that the emitted light may be monochromatic and stable. The design flexibility of ECLs makes them useful in applications that utilize wavelength control and stability. In telecommunications, ECLs may be used as sources for dense wavelength-division multiplexing (DWDM) systems. In spectroscopy and sensing, ECLs may be used to selectively probe specific molecular transitions. Additionally, ECLs may be used in metrology, atomic physics, and/or as seed lasers for high-power amplifiers. The ability of ECLs to combine wide tunability, narrow linewidth, and stable operation distinguishes ECLs from many other laser types, such as integrated cavity lasers.

### SUMMARY

In some implementations, an apparatus may include a gain chip, within a cavity of the apparatus, configured to emit a light beam; a tunable wavelength selection component, within the cavity, configured to filter the light beam into a first plurality of tunable transmission channels separated by a free spectral range; and a bandpass component, within the cavity, configured to define a spectral bandpass that enables a second plurality of tunable transmission channels that form a multi-channel light beam for output from the cavity, wherein the second plurality of tunable transmission channels is a subset of the first plurality of tunable transmission channels that falls within the spectral bandpass.

In some implementations, a laser system may include a gain chip, within a cavity of the laser system, configured to emit a light beam; a tunable wavelength selection component, within the cavity, configured to filter the light beam into a first plurality of tunable transmission channels separated by a free spectral range; and a bandpass component, within the cavity, configured to define a spectral bandpass that enables a second plurality of tunable transmission channels that form a multi-channel light beam for output from the cavity, wherein the second plurality of tunable transmission channels is a subset of the first plurality of tunable transmission channels that falls within the spectral bandpass.

In some implementations, an ECL may include a gain chip, within a cavity of the ECL, configured to emit a light beam; a tunable wavelength selection component, within the cavity, configured to filter the light beam into a first plurality of tunable transmission channels separated by a free spectral range; and a bandpass component, within the cavity, configured to define a spectral bandpass that enables a second plurality of tunable transmission channels that form a multi-channel light beam for output from the cavity, wherein the second plurality of tunable transmission channels is a subset of the first plurality of tunable transmission channels that falls within the spectral bandpass.

### BRIEF DESCRIPTION OF THE DRAWINGS

FIG. 1 shows a side view of a laser system.

FIG. 2 shows a plot of a frequency-channel profile for a multi-channel tunable laser.

### DETAILED DESCRIPTION

The following detailed description of example implementations refers to the accompanying drawings. The same reference numbers in different drawings may identify the same or similar elements.

A tunable laser configuration for a single-wavelength laser (e.g., a tunable telecommunications laser, referred to as an external-cavity laser (ECL)) represents a laser design in the field of optical communications. Conversely to an integrated cavity laser, where the laser resonator cavity is compact and closely surrounds the gain-chip medium, the ECL features a more expansive configuration. For instance, in an ECL, at least one end mirror of the cavity is positioned remotely from the gain chip, and additional optical elements may be placed between the gain chip and the remote end mirror. This configuration allows for greater flexibility and control over the laser output, making ECL configurations valuable for various high-precision applications of optical communications.

Additionally, ECL configurations have the ability to achieve single-wavelength operation with wide frequency tunability. This frequency tunability is accomplished through the use of two optical comb filters (such as Fabry-Perot etalons, among other examples) within the laser cavity of the ECL. At least one of these filters is tunable, such as via thermal adjustments. The filters may be designed such that an associated free-spectral range (FSR) (e.g., the spacing between the comb teeth) differs between the two filters. This difference in FSR ensures that there is only one overlapping tooth from the first filter and the second filter within the gain wavelength window of the laser. As a result, the one wavelength that falls within this narrow overlap window can resonate and amplify within the laser cavity, leading to lasing within the overlap wavelength.

The laser cavity of the ECL functions as a comb filter with narrow and densely packed teeth. The structure of the ECL laser cavity is configured to ensure that one cavity mode aligns with the overlapping tooth of the two filters. In some examples, the Vernier effect allows for broader wavelength tuning. The Vernier meshing mechanism enables the single overlap wavelength to be adjusted over a spectrum that is wider than the tuning range of the filter.

However, the single-wavelength output of ECLs presents limitations in the context of optical communication demands. The ongoing trend of driving optical data connections closer to the chip, coupled with the ever-increasing overall bandwidth demands, places pressure on the bandwidth capacity of optical-communication technologies. Accordingly, the development of multi-wavelength optical sources may enable optical technologies to keep pace with the increasing bandwidth demand. However, improvements to an ECL may be desired across various parameters, including operational efficiency, integration, compactness, wavelength control, wavelength selection, per-wavelength output power, and cost efficiency. Single-wavelength ECLs, while precise and stable, do not inherently support the simultaneous multi-wavelength operation associated with dense wavelength division multiplexing (DWDM) systems and other advanced optical communication applications.

Some implementations described herein provide a multi-wavelength tunable laser (e.g., a multi-wavelength or multi-channel ECL) that is capable of simultaneous multi-wavelength operation. For example, the multi-wavelength ECL may include an internal comb filter that is paired with a bandpass filter such that a selected N adjacent teeth of the comb filter will fall within the passband of the bandpass filter (e.g., N=8; N=16; or another value determined by design choice). Accordingly, the laser cavity of the multi-wavelength ECL can resonate, have gain, and/or lase at N wavelengths simultaneously (the cavity mode under each of the N adjacent comb teeth within the bandpass passband). Additionally, the multi-wavelength ECL may include one or more semiconductor amplifiers (e.g., one or more semiconductor optical amplifiers (SOAs). In some implementations, the one or more semiconductor amplifiers may be “inhomogeneously broadened” (e.g., broadening of the spectral lines or energy levels of the semiconductor material due to variations in the local environment within the material). Accordingly, with the inhomogeneous broadening, multiple wavelengths can be amplified simultaneously by an SOA without significantly competing with each other for the same gain medium resources. Therefore, the techniques described herein enable a multi-wavelength ECL to stably lase at the N wavelengths. In some implementations, the cavity comb filter of the multi-wavelength ECL may be tunable to adjust the grid within the bandpass window, enabling tuning (e.g., wavelength shifting) of the entire block of N wavelengths.

In some examples, the multi-wavelength ECL may include a gain chip (e.g., a conventional band (C-band), a long band (L-band), or an original band (O-band)), a monitor photodiode (PD), a collimating lens, an optical mirror, a heating component, an integrated resistance temperature device (RTD) with an optical comb filter, an optical isolator, a fiber focus lens, and/or bandpass optical filter that are combined to generate multi-wavelength laser output for a single optical fiber. In addition, the RTD may be used to monitor the temperature with a feedback control loop for temperature control of the comb filter. Accordingly, the muti-wavelength laser can be moved to a desirable frequency-grid target within the range of the bandpass filter. In addition, this multi-channel laser can be focused into a single output fiber to distribute multi-wavelength lasing simultaneously. Furthermore, this multi-wavelength laser can tune multiple wavelengths simultaneously within a range of the bandpass filter. This can create an efficient way to communicate and transmit data in a parallel manner between two communication entities (such as multiple data center systems). Therefore, the techniques described herein enable implementation of a multi-wavelength tunable laser that leverages the lasing precision techniques of single-wavelength ECLs while enabling simultaneous multi-wavelength communication operations.

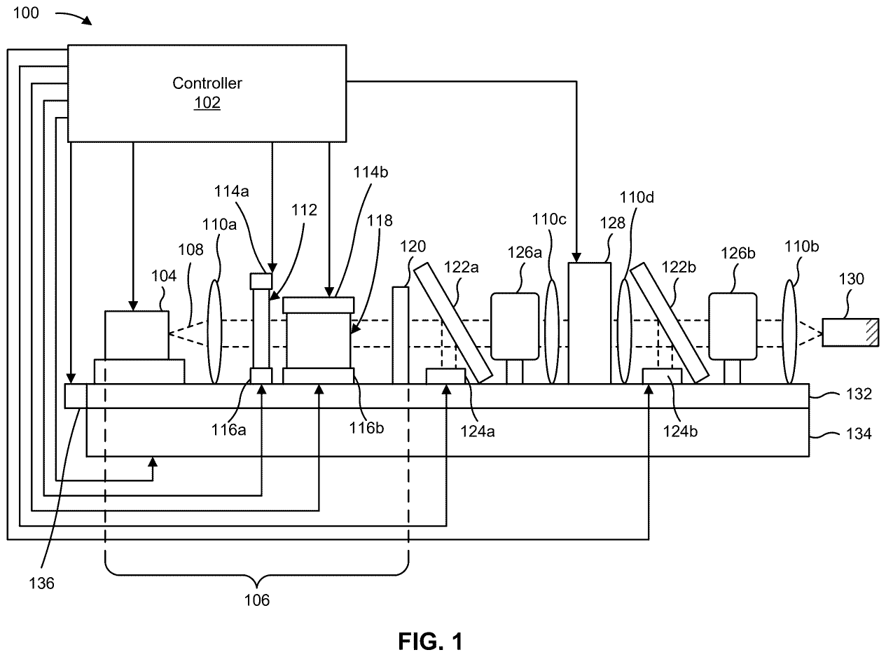

FIG. 1 shows a side view of a laser system 100. In some examples, the laser system 100 may be a multi-wavelength tunable laser (such as a multi-wavelength ECL). As shown in FIG. 1, the laser system 100 includes a controller 102, a gain chip 104, a lasing cavity 106, a light beam 108, lenses 110 (e.g., lens 110a, lens 110b, lens 110c, and lens 110d), a tunable wavelength selection component 112, one or more temperature sensors (e.g., temperature sensor 116a and/or temperature sensor 116b), one or more heating components 114 (e.g., heating component 114a and/or heating component 114b), a bandpass component 118, a reflector 120, one or more splitter components 122 (e.g., splitter component 122a and/or splitter component 122b), one or more photodiodes 124 (e.g., photodiode 124a and/or photodiode 124b), one or more isolator components 126 (e.g., isolator component 126a and/or isolator component 126b), an optical amplifier 128, an output fiber 130, a carrier 132, a thermo-electric cooler (TEC) 134, and a thermistor 136. In some other implementations, the laser system 100 may include additional and/or different components in addition to or in absence of the components described with reference to FIG. 1.

The controller 102 may include memory. For example, the memory of the controller 102 may include random access memory (RAM), read only memory (ROM), a hard disk drive, and/or another type of memory (e.g., a flash memory, a magnetic memory, and/or an optical memory). The memory may include internal memory (e.g., RAM, ROM, or a hard disk drive) and/or removable memory (e.g., removable via a universal serial bus connection). The memory may be a non-transitory computer-readable medium. The memory may store information, one or more instructions, and/or software (e.g., one or more software applications) related to the operation of the laser system 100. For instance, the memory may store one or more instructions that (when performed by one or more processors of the controller 102) enable one or more operations of the laser system 100. In some aspects, the memory may include one or more memories that are coupled (e.g., communicatively coupled) to one or more processors, such as via a bus. Communicative coupling between a processor and a memory at the controller 102 may enable the processor to read and/or process information stored in the memory and/or to store information in the memory. The processor of the controller 102 may include a central processing unit, a graphics processing unit, a microprocessor, a microcontroller, a digital signal processor, a field-programmable gate array, an application-specific integrated circuit, and/or another type of processing component. The processor may be implemented in hardware, firmware, or a combination of hardware and software. In some aspects, the processor may include one or more processors capable of being programmed to perform one or more operations or processes described elsewhere herein.

As shown in FIG. 1, the controller 102 may be coupled to one or components of the lasers system 100, such as via one or more buses. A bus may include one or more components that enable wired and/or wireless communication among the components of the laser system 100. The one or more buses may couple one or more or more components of FIG. 1 to the controller 102, such as via operative coupling, communicative coupling, electronic coupling, and/or electric coupling. For example, the one or more buses may include an electrical connection (e.g., a wire, a trace, and/or a lead) and/or a wireless bus. As shown in FIG. 1, the controller 102 may be coupled to the gain chip 104, the heating components 114, the temperature sensors 116, the photodiodes 124, the optical amplifier 128, the TEC 134, and/or the thermistor 136. In other implementations, the controller 102 may be coupled to any of the components shown in FIG. 1 (e.g., via one or more buses).

The gain chip 104 may be a semiconductor device designed to provide optical gain in specific wavelength bands such as the C-band (1530-1565 nanometers (nm)), L-band (1565-1625 nm), and/or O-band (1260-1360 nm), among other examples. Accordingly, the gain chip 104 may amplify optical signals in fiber optic communication systems, enhancing signal strength and extending transmission distances. The TEC 134 may be operatively coupled to gain chip 104 to thermally stabilize the distance between front and back facets of the gain chip 104 and/or provide for stable output from the gain chip 104. The TEC 134 may be operatively coupled to controller 102.

As shown in FIG. 1, the portion of the laser system 100 that spans from the gain chip 104 and the reflector 120 forms the lasing cavity 106. The lasing cavity 106 may be the optical path where light amplification and feedback occur, enabling sustained laser oscillation. This cavity extends from one end of the gain chip 104 (e.g., the left-most side of the gain chip 104, in FIG. 1) out to the reflector 120 (such as an end mirror or diffraction grating) and back. The reflector 120, positioned outside of and/or separate from the gain chip 104, serves as a reflective surface that returns a portion of the emitted light back into the gain medium, providing the optical feedback used to maintain lasing. Additionally, the gain chip 104 may include a reflective coating on the back side of the gain chip 104, which acts as a second mirror. Together, the reflector 120 and the back facet of the gain chip 104 form a mirror pair, defining the two ends of the lasing cavity 106. This configuration ensures that light bounces back and forth between these two mirrors, passing through the gain medium multiple times to achieve amplification and coherent light emission. Accordingly, a facet of the gain chip 104 and the reflector, optically couplable to the gain chip 104, may define the lasing cavity of the laser system 100. In some implementations, the mirror coupled to the gain chip 104 (that forms the mirror pair with the reflector 120) may be separate from the gain chip 104.

Additionally, the gain chip 104, within the lasing cavity 106, may be configured to emit a light beam 108. The gain chip 104 may act as the active medium that amplifies light through the process of stimulated emission. When electrical current is injected into the gain chip 104 (e.g., via the controller 102), the electrical current excites electrons within the semiconductor material, allowing them to release photons as the electrons return to a lower energy state. This process may not produce light at a single, fixed wavelength, but rather the gain chip 104 supports the amplification of light over a range of frequencies (or a bandwidth) determined by the physical properties of the semiconductor material and the structure of the gain chip 104. This frequency bandwidth defines the set of wavelengths within which the gain chip 104 can efficiently generate and amplify light. In other words, the gain chip 104 is configured to emit the light beam 108 which spans the spectrum of possible wavelengths.

After the light beam 108 is generated by the gain chip 104, the light beam 108 may emerge as a divergent beam (e.g., due to the small size of the emission area on the gain chip 104). To efficiently guide this light beam 108 along a defined optical path and into the external cavity, the lens 110a (e.g., a collimating lens) may be placed in front of the emitting facet of the gain chip 104. The lens 110a may collect the spreading light rays and refocus them to travel parallel to one another, producing a collimated or quasi-collimated beam. Collimation may reduce optical losses, ensuring that the light beam 108 interacts effectively with external cavity components, and may maintain the spatial coherence of the light beam 108 over the length of the lasing cavity 106. By shaping the light into a well-defined, parallel beam, the lens 110a helps to establish a stable and efficient optical path between the gain chip 104 and the reflector 120. In some implementations, the lens 110d may also be a re-collimating lens (e.g., improving the collimation of the light beam 108 that may output from the optical amplifier 128).

As shown in FIG. 1, after collimation via the lens 110a, the light beam 108 enters the tunable wavelength selection component 112 (e.g., a comb filter). The tunable wavelength selection component 112 may be an example of an etalon filter. For example, an etalon filter is an optical device that includes two parallel, partially-reflective surfaces that create multiple internal reflections of light passing through. The internal reflections cause interference between the reflected light waves, leading to the formation of transmission peaks at specific wavelengths where constructive interference occurs. The spacing between these peaks (e.g., the FSR) may be determined by the distance between the reflective surfaces and the refractive index of the material between them. Therefore, the tunable wavelength selection component 112, within the lasing cavity 106, may be configured to filter the light beam 108 into a first plurality of tunable transmission channels separated by the configured FSR.

In the lasing system 100, the tunable wavelength selection component 112 may have an FSR of 200 gigahertz (GHz), may have a thickness of approximately 200 micrometers (μm), and may comprise silicon. In other implementations, the tunable wavelength selection component 112 may have a different FSR, a different thickness, and/or be comprised of a different material. In some other implementations, the tunable wavelength selection component 112 may not be an etalon filter, but rather a different type of filter (e.g., a silicon photonic ring resonator filter or a distributed Bragg reflector (DBR) grating filter can also be used to provide the same or similar function of an etalon filter). For instance, the tunable wavelength selection component 112 may be a silicon ring resonator, which can be configured with the same FSR (e.g., 200 GHz) as the etalon filter described herein. Alternatively, the tunable wavelength selection component 112 may be a DBR grating filter, where the Bragg grating periodicity of the DBR grating filter matches the FSR of the etalon filter described herein. In implementations where the tunable wavelength selection component 112 is a DBR grating filter, a back side of the gain chip 104 may have an integrated reflector that may serve as a first mirror of a DBR mirror pair, and the DBR grating filter may include a second mirror of the DBR mirror pair.

In some implementations, the temperature sensor 116a (e.g., an RTD) and/or the heating component 114a may be attached to the tunable wavelength selection component 112.

The temperature sensor 116a and/or the heating component 114a may be configured to measure and control a temperature of the tunable wavelength selection component 112, and accordingly, one or more optical properties of the tunable wavelength selection component 112 that are temperature dependent (such as transmission peaks of the tunable wavelength selection component 112). For instance, the temperature sensor 116a measures the temperature of the tunable wavelength selection component 112 and the heating component 114a applies heat to the tunable wavelength selection component 112 to maintain a selected operating temperature of the tunable wavelength selection component 112. By regulating to a consistent temperature, the tunable wavelength selection component 112 can reliably separate and/or filter optical signals spaced in accordance with the FSR (defined by the tunable wavelength selection component 112), ensuring stable and accurate performance in applications such as wavelength-division multiplexing in optical communication systems. Changing the heat applied to the tunable wavelength selection component 112 alters the temperature, which affects both the refractive index and the physical spacing between the reflective surfaces of the tunable wavelength selection component 112. As a result, the resonant wavelengths (or frequencies) at which the tunable wavelength selection component 112 transmits light shift accordingly. By increasing or decreasing the temperature, the transmission peaks of the etalon filter move to longer (e.g., redshift) or shorter (e.g., blueshift) wavelengths, respectively. This thermal tuning allows precise control over the output wavelengths or frequencies of the first plurality of channels transmitted through the tunable wavelength selection component 112, enabling dynamic selection or adjustment of the multi-channel light beam.

In some examples, the thermistor 136 (e.g., on the optical carrier 132 and/or TEC 134) may be used to calibrate the temperature sensor 116a. For instance, during calibration, the thermistor 136 may be placed in close thermal contact with the carrier 132 to measure a temperature of the carrier 132. Accordingly, the TEC 134 may be configured to control the temperature of the carrier 132, allowing comparison and adjustment of temperature readings of the temperature sensor 116a relative to the measurements from the thermistor 136, ensuring that the temperature sensor 116a provides accurate temperature readings for the tunable wavelength selection component 112. After calibration of the temperature sensor 116a, a wavelength meter may be used to calibrate a temperature of the tunable wavelength selection component 112 and temperature sensor 116a versus a frequency output of the tunable wavelength selection component 112. For example, the tunable wavelength selection component 112 may be stabilized at various known temperatures using the calibrated temperature sensor 116a, and the corresponding transmission peaks at the known temperatures may be recorded with the wavelength meter. By plotting the measured wavelengths of the transmission peaks against the known temperatures, a relationship between the temperature and the resonant frequencies of the tunable wavelength selection component 112 may be established. Based on establishing the temperature-to-frequency relationship of the tunable wavelength selection component 112, multiple frequencies respectively associated with multiple lasing channel outputs of the laser system 100 may be tuned simultaneously by controlling the temperature of the tunable wavelength selection component 112. In other words, a target operating frequency of the tunable wavelength selection component 112 can be moved within a tunable range by changing the temperature of the tunable wavelength selection component 112 with the temperature sensor 116a and heating component 114a. In some implementations, the tunable wavelength selection component 112 sits on the same carrier 132 and TEC 134 as the gain chip 104.

In some implementations, the thermistor 136, that may be attached to the carrier 132, may be configured to read a temperature of the carrier 132. Accordingly, the controller 102, operatively coupled to the thermistor 136 and the TEC 134, may be configured to apply a current to the TEC 134 based on the temperature of the carrier 132, where the TEC 134 may maintain the temperature of the carrier 132 within a temperature range based on the current. The TEC 134 may operate on the Peltier effect, which enables the TEC 134 to transfer heat from one side of the TEC 134 to the other if an electric current is applied. If the controller 102 receives a temperature reading from the thermistor 136 indicating that the carrier 132 has deviated outside of the configured temperature range, the controller 102 adjusts the current supplied to the TEC 134 accordingly. If the carrier 132 becomes too warm (e.g., greater than the temperature range), the controller 102 increases the current in a direction that causes the TEC 134 to absorb heat from the carrier 132 and dissipate heat to a heat sink (not shown) or the surrounding environment, effectively cooling the carrier 132. Conversely, if the carrier 132 is too cool (e.g., less than the temperature range), the controller 102 can reverse or modulate the current, prompting the TEC 134 to transfer heat toward the carrier 132, thereby raising the temperature of the carrier 132. This closed-loop feedback system allows for temperature regulation, as the controller 102 can vary the magnitude and direction of the applied current to the TEC 134. As a result, the carrier 132 (which may support multiple optical or electronic components shown in FIG. 1) remains within the configured temperature range, reducing thermally induced drifts and instabilities of the laser system 100.

The bandpass component 118 (e.g., an optical bandpass component 118) may be designed to select multiple lasing channels for output at the laser system 100. For example, the bandpass component 118 may be configured with a passband that defines a range of wavelengths or frequencies that the tunable wavelength selection component 112 allows to pass through while blocking wavelengths or frequencies outside this range. Accordingly, the passband of the bandpass component 118 may be configured such that a number of lasing channels (output by the tunable wavelength selection component 112) falls within the passband. In some examples, the number of lasing channels (N) may be any integer (e.g., N=8, N=16, among other examples). By controlling the passband, the bandpass component 118 ensures that the targeted N lasing channel outputs are utilized, enhancing the performance and efficiency of the laser system 100. Therefore, the bandpass component 118, within the lasing cavity 106, may be configured to define a spectral bandpass that enables a second plurality of tunable transmission channels that form a multi-channel light beam for output from the lasing cavity 106. For example, the second plurality of tunable transmission channels may be a subset of the first plurality of tunable transmission channels that falls within the spectral bandpass. Accordingly, the bandpass component 118 may be configured to allow the second plurality of tunable transmission channels to contain a defined number of tunable transmission channels.

In some implementations, the bandpass component 118 may comprise a block composed primarily of silicon, a material used in photonic applications due optical transparency in the near-infrared spectrum and compatibility with modern fabrication techniques. Structurally, this silicon block is designed with a planar geometry to facilitate integration within the optical path of the lasing cavity 106. One face of the silicon block (e.g., either the front face oriented toward the gain chip 104 or the back face positioned farther from the gain chip 104) may be coated with a dedicated bandpass filter material. This filter material may comprise a multi-layer thin-film stack engineered using alternating layers of dielectric substances with differing refractive indices. These alternating layers may be deposited to create constructive and destructive interference at specific wavelengths, thereby defining a spectral passband of the bandpass component 118. In some cases, the bandpass component 118 may be positioned on the opposite side of the gain chip 104 (such geometry not depicted in FIG. 1) and also provide the mirror that forms the mirror pair with the reflector 120.

In some implementations, the temperature sensor 116b (such as an RTD) and/or the heating component 114b may be physically attached to the bandpass component 118. These elements may be configured to monitor and regulate the temperature of the bandpass component 118. By actively controlling the temperature, the controller 102 can finely tune and stabilize one or more optical properties of the bandpass component 118 that are known to be temperature dependent. For instance, the bandpass component 118 (which may be implemented as an interference filter, a thin-film filter, or a Bragg grating, among other examples) may be designed to selectively transmit light within a specific wavelength range while attenuating light outside of that range. One or more optical properties of the bandpass component 118 that may change with temperature include a center wavelength (or peak transmission wavelength), bandwidth, and/or the transmission profile or shape. The center wavelength of an optical bandpass component 118 may be sensitive to temperature based on the thermo-optic effect (e.g., the change in refractive index of materials with temperature) and/or the coefficient of thermal expansion (e.g., the physical change in thickness or periodicity of the filter layers or grating). For thin-film interference filters, an increase in temperature may cause the refractive index of the dielectric materials to change and may also alter the physical thickness of the layers, resulting in a shift of the center wavelength (e.g., referred to as a “wavelength drift”). Additionally, or alternatively, the bandwidth (e.g., full width at half maximum (FWHM)) of the bandpass component 118 may broaden or narrow with temperature changes, as the constructive and destructive interference conditions are altered. For Bragg gratings used as bandpass elements, thermal expansion and the thermo-optic effect change the grating period and the effective refractive index, resulting in a shift in the reflected or transmitted wavelength. By integrating the temperature sensor 116b and heating component 114b with the bandpass component 118, the laser system 100 can employ active feedback control to stabilize the temperature of the bandpass component 118, thus increasing control over the center wavelength, bandwidth, and/or overall filter response. This ensures consistent and reliable optical performance, even in the presence of ambient temperature fluctuations or thermal loads generated by other components of the laser system 100.

Accordingly, by controlling the temperature of the bandpass component 118 with the temperature sensor 116b and the heating component 114b, the controller 102 can dynamically influence the number of lasing channels (or distinct wavelengths) present in the light beam 108 that output from the lasing cavity 106. As the temperature is adjusted, the central wavelength and bandwidth of the bandpass component 118 shift accordingly, enabling selective alignment of the bandpass component 118 transmission peaks with the gain profile of the laser medium.

Therefore, as described herein, the heating components 114a and 114b, attached to the tunable wavelength selection component 112 and to the bandpass component 118, may be configured to apply heat to the tunable wavelength selection component 112 and to the bandpass component 118. Additionally, the temperature sensors 116a and 116b, attached to the tunable wavelength selection component 112 and to the bandpass component 118, may be configured to monitor a temperature of the tunable wavelength selection component 112 and the bandpass component 118. Accordingly, the controller 102, operatively coupled to the heating components 114a and 114b and the temperature sensors 116a and 116b, may be configured to adjust a plurality of wavelengths corresponding to the second plurality of tunable transmission channels based on adjusting a temperature output of the heating components 114a and 114b. In some implementations, the temperature sensors 116a and 116b may be a same temperature sensor or different/separate temperature sensors. In some implementations, the heating components 114a and 114b may be a same heating component or different/separate heating components.

In some implementations, the bandpass component 118 may enable fine adjustments to the length of the lasing cavity 106 and thus wavelengths of the cavity modes. For example, the heating component 114b and the temperature sensor 116b, both attached to or in thermal contact with the bandpass component 118, may allow for precise temperature control of the silicon block and its bandpass filter face. When heat is applied via the heating component 114b, the temperature of the silicon block increases, causing the bandpass component 118 to expand due to the coefficient of thermal expansion. This physical expansion results in a slight increase in the optical path length between the gain chip 104 and the reflector 120, thereby increasing the overall length of the lasing cavity 106. Conversely, reducing the temperature using the heating component 114b (or by allowing the component to cool) causes the bandpass component 118 to contract, shortening the lasing cavity length. Additionally, or alternatively, the TEC 134 can be used to adjust the lasing cavity 106 length by controlling the temperature of the carrier 132, upon which the gain chip 104, and in some implementations, the bandpass component 118 or the tunable wavelength selection component 112, may be mounted. By increasing the current supplied to the TEC 134, the carrier 132 can be heated, causing it to expand and thereby increasing the distance between components at either end of the lasing cavity 106, which effectively lengthens the optical path. Conversely, reversing or reducing the current to the TEC 134 allows the carrier to cool and contract, decreasing the lasing cavity 106 length. These thermal tuning mechanisms, whether applied locally via the heating component 114b or globally via the TEC 134, provide precise and dynamic control over the lasing cavity 106 physical length, enabling robust wavelength stabilization and agile tuning required for high-performance multi-wavelength laser systems.

The splitter component 122a may be used to divide the light beam 108 into two separate paths. In other words, the splitter component 122a may be configured to reflect a portion of the multi-channel light beam (e.g., to the photodiode 124a). For instance, a first path of the light beam 108 may continue to the intended application, while a second path is directed to the photodiode 124a. The photodiode 124a may be used to monitor output power with closed loop feedback to control the output power and a gain medium current. For example, the gain medium current directly influences the amplification of the light within the lasing cavity 106, and the photodiode 124a periodically monitors the output power of the laser. The feedback control loop uses the measurements from the photodiode 124a to adjust the gain medium current in real-time, ensuring that the output power of the laser system 100 remains stable and at a configured level. Accordingly, the photodiode 124a is configured to receive a portion of the light beam 108 and generate a current value that is proportional to an output power of the light beam 108, where the controller 102 may receive or obtain the current value from the photodiode 124a. Additionally, as show in FIG. 1, the controller 102 is operatively coupled to the photodiode 124a and one or more of the gain chip 104, and may be configured to adjust a first current applied to the gain chip 104 based on the current value measured by the photodiode 124a, where the first current or controls the output power or intensity of the light beam 108. While FIG. 1 illustrates the photodiode 124a and the splitter component 122a outside of the lasing cavity 106 (e.g., after the reflector 120), in other implementations the photodiode 124a and the splitter component 122a may reside inside or within the lasing cavity 106. For instance, the photodiode 124a and the splitter component 122a may reside between the lens 110a and the tunable wavelength selection component 112, between the tunable wavelength selection component 112 and the bandpass component 118, or between the bandpass component 118 and the reflector 120.

In some implementations, the splitter component 122b may be used to divide the light beam 108 into two separate paths, after the light beam traverses past the optical amplifier 128. In other words, the splitter component 122b may be configured to reflect a portion of the multi-channel light beam (e.g., to the photodiode 124b). For instance, a first path of the light beam 108 may continue to the intended application, while a second path is directed to the photodiode 124b. The photodiode 124a may be used to monitor output power with closed loop feedback to control the current and output power of the optical amplifier 128. For example, the current applied to the optical amplifier 128 may directly influence the amplification of the light beam 108 after the optical amplifier 128, and the photodiode 124b may periodically monitor the output power of the light beam 108 that may be amplified by the optical amplifier 128. The feedback control loop uses the measurements from the photodiode 124b to adjust the current applied to the optical amplifier 128 in real-time, ensuring that the output power of the laser system 100 remains stable and at a configured level. Accordingly, the photodiode 124b is configured to receive a portion of the light beam 108, after the optical amplifier 128, and generate a current value that is proportional to an output power of the light beam 108, where the controller 102 may receive or obtain the current value from the photodiode 124b. Additionally, as show in FIG. 1, the controller 102 is operatively coupled to the photodiode 124b and the optical amplifier 128, and may be configured to adjust a second current applied to the optical amplifier 128 based on the current value measured by the photodiode 124b, where the second current controls the output power or intensity of the light beam 108. While FIG. 1 illustrates the photodiode 124b and the splitter component 122b directly after the optical amplifier 128, in other implementations the photodiode 124b and the splitter component 122b may be positioned anywhere after the optical amplifier 128 and before the lens 110b (e.g., between the optical amplifier 128 and the isolator component 126b or between the isolator component 126b and the lens 110b). In some implementations, the photodiode 124b and the splitter component 122b may be optional to the laser system 100.

Outside of the lasing cavity 106, the isolator component 126a may be configured to prevent back-reflections from propagating back into the lasing cavity 106 and/or other sensitive components of the laser system 100. By allowing light beam 108 to pass in one direction, the isolator component 126a protects the laser system 100 from potential disruptions or instabilities caused by reflected light, ensuring stable and efficient operation. In the context of ECLs, such isolator components 126 may be advantageous based on the sensitivity of ECLs to feedback, which can degrade spectral purity, destabilize the emission wavelength, and/or induce mode hopping. The isolator components 126 may be implemented using a variety of optical isolator technologies. For example, the isolator components 126 may include a Faraday isolator, which uses the magneto-optic Faraday effect to rotate the polarization of light in the presence of a magnetic field. Additionally, or alternatively, the isolator components 126 may be constructed using polarizers and waveplates, such as a combination of a polarizing beamsplitter and a quarter-wave plate, to achieve unidirectional transmission of the light beam 108. Accordingly, the isolator component 126a may be configured to prevent optical back-reflection into the lasing cavity 106 of the laser system 100.

The lens 110b may be a fiber focus lens. For example, a fiber focus lens can focus the multi-wavelength laser beam of the laser system 100 into the core of a single optical fiber. Therefore, each of the N lasing channel outputs of the light beam 108 are focused into a single optical fiber (e.g., output fiber 130) for output from the laser system 100. By accurately aligning and concentrating the light beam 108, the lens 100b enables efficient coupling of the laser output into the output fiber 130, reducing losses and increasing the transmission of the optical signal through the output fiber 130.

In some embodiments of the laser system 100, the optical amplifier 128, such as an SOA, and a second isolator component (e.g., the isolator component 126b) may be positioned in the optical path between the isolator component 126a and the lens 110b. The sequence of isolator component 126a, followed by the optical amplifier 128, then the isolator component 126b, and followed by the lens 110b may increase the stability and output performance of the laser system 100. For example, the isolator component 126a protects the gain chip 104 and other sensitive upstream components within the lasing cavity 106 from back-reflections that may destabilize or disrupt laser operation. The optical amplifier 128, positioned downstream of the isolator component 126a, may be configured to increase the output power of the multi-channel light beam 108, compensating for losses in the optical path and enabling strong signal delivery to the output fiber 130. An optical amplifier 128, such as an SOA, amplifies light signals directly using stimulated emission within a semiconductor medium, and may be capable of boosting multiple wavelength channels simultaneously, making the optical amplifier 128 well-suited for wavelength-division multiplexed (WDM) systems. In some implementations, lens 110c may also be a focus lens (e.g., focus the light beam 108 into an input of the optical amplifier 128).

The inclusion of the isolator component 126b after the optical amplifier 128 may be advantageous, as the optical amplifier 128 may also be sensitive to optical feedback. Any back-reflected light (such as that arising from the lens 110b, connector interfaces, or the output fiber 130) that re-enters the optical amplifier 128 may induce unwanted effects such as gain fluctuations, noise, or parasitic lasing. This can degrade the performance of the optical amplifier 128 and, by extension, the overall laser system 100. By situating the isolator component 126b downstream of the optical amplifier 128, the laser system 100 effectively blocks these back-reflections from reaching and destabilizing the optical amplifier 128 and upstream components. This arrangement ensures that the amplified light is delivered efficiently and stably to the output fiber 130 via the lens 110b, while maintaining both the integrity and reliability of the laser system 100.

The laser system 100 may differ from other laser systems, such as a comb laser. For example, a comb laser is a mode-locked laser that utilizes the physical relationship of a continuous stream of coherent optical pulses being equivalent to a grid of continuous wave (CW) optical wavelengths (e.g., each filter of a comb laser stores incident pulses and releases CW light of a specific wavelength). However, comb lasers have certain fundamental characteristics that may make them less preferable than the techniques employed by the laser system 100. For example, the laser system 100 may be more power efficient than a comb laser, based on comb lasers generating multiple wavelengths that are later filtered out, resulting in wasted power. Conversely, each of the N lasing channel outputs of the laser system 100 may be utilized, increasing the energy efficiency of the laser system 100 relative to a comb laser. Additionally, comb lasers may exhibit less uniformity across the desired wavelengths compared to the laser system 100, which can be problematic when a consistent power output is required across all channels. Therefore, the laser system 100 may be more energy efficient and is associated with a more uniform laser output compared to comb laser, which is beneficial in multi-wavelength optical communications.

As indicated above, FIG. 1 is provided as an example. Other examples may differ from what is shown in and described with regard to FIG. 1.

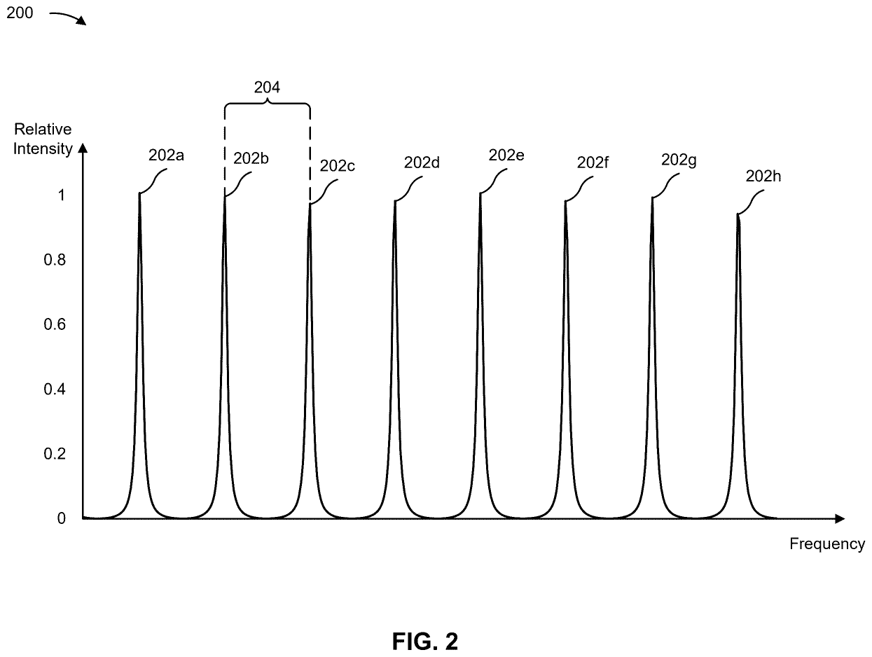

FIG. 2 shows a plot 200 of a frequency-channel profile for a multi-channel tunable laser. In some examples, the frequency-channel profile may be an example frequency-channel profile of the laser system 100. The plot 200 illustrates the relative output intensity of the laser system 100 across a range of frequencies. WDM laser channel grids are typically defined by the laser frequencies but often expressed as “wavelength” channels. There is a correspondence of optical frequency to optical wavelength through the fundamental relationship λ (optical wavelength)·f (optical frequency)=c (natural speed of light).

As shown in FIG. 2, the laser system 100 outputs the light beam 108, which includes multiple laser-frequency transmission channels 202, to the output fiber 130 (e.g., after passing through the tunable wavelength selection component 112 and the bandpass component 118). As described herein, after the light beam 108 passes through the tunable wavelength selection component 112, the light beam 108 may include a first plurality of transmission channels 202 (e.g., tunable transmission channels). For instance, after passing through the tunable wavelength selection component 112, the light beam 108 can emerge including a first plurality of transmission channels 202, each corresponding to a narrow band of wavelengths or frequencies. The separation in frequency or wavelength between these transmission channels 202 may be governed by the FSR 204 of the tunable wavelength selection component 112. The FSR 204 may be defined as the spacing between consecutive transmission channels 202 and may be based on the physical thickness and the refractive index of the tunable wavelength selection component 112. Specifically, the FSR 204 may be the frequency interval over which the phase difference between successive reflections in the tunable wavelength selection component 112 increases by 2π, resulting in constructive interference at discrete intervals. For example, in FIG. 2, the tunable wavelength selection component 112 has the FSR 204, such that each transmission channel 202 is separated from the next by the FSR 204. In optical terms, “transmission channel” refers to a distinct, narrow frequency (or wavelength) band within the broader optical spectrum, which may be used to carry separate data streams in WDM communication systems or to define individual laser modes. Thus, the tunable wavelength selection component 112 enables the generation of a multi-channel light beam, with each transmission channel 202 spaced according to the FSR 204. Accordingly, the FSR 204 defines a fixed channel spacing between the transmission channels 202.

Additionally, the first plurality of transmission channels 202 (that exits from the tunable wavelength selection component 112) may propagate to the bandpass component 118, which may block any transmission channels 202 of the first plurality that do not fall within the passband of the bandpass component 118. For example, in FIG. 2, the passband of the bandpass component 118 may allow a subset of transmission channels 202 that are within the passband. For instance, in one example, the passband may span from 194 terahertz (THz) to 195.4 THz. In other examples, however, the passband may span any portion of contiguous frequencies covered by the a the C-band, the L-band, and/or the O-band.

As shown in FIG. 2, the passband allows for 8 consecutive transmission channels 202 to pass through the bandpass component 118 (e.g., transmission channels 202a, 202b, 202c, 202d, 202e, 202f, 202g, and 202h) that are each evenly spaced apart in the frequency domain. That is the distance between the transmission channel 202a and 202b is equal to the distance between transmission channel 202b and 202c (e.g., as defined by the FSR 204). Accordingly, the bandpass component 118 allows for the propagation of a second plurality of transmission channels 202 which may be a subset of the first plurality of transmission channels 202. While FIG. 2 illustrates 8 transmission channels 202, in other implementations the bandpass component 118 may be configured to allow a defined number of N transmission channels 202 (e.g., 8, 16, or any other number).

As described herein, the tunable wavelength selection component 112 may be configured to simultaneously shift the frequencies of the second plurality of transmission channels 202. For example, by increasing or decreasing the temperature of the tunable wavelength selection component 112 (e.g., via the heating component 114a), the controller 102 may concurrently increase or decrease the second plurality of transmission channels 202 by the same frequency shift. For instance, as shown in FIG. 2, the transmission channel 202a is centered at a first frequency and the transmission channel 202b is centered at a second frequency. Accordingly, the controller 102 may apply heat to the tunable wavelength selection component 112 to shift the first transmission channel 202a to any frequency from the first frequency to the second frequency (e.g., moving each of the transmission channels 202 by the same frequency shift). In other words, the controller 102 may be operable to concurrently shift the second plurality of wavelengths across the optical spectrum.

This simultaneous frequency shifting capability of the laser system 100 allows for each of the transmission channels 202 produced by the tunable wavelength selection component 112 to be tuned (or translated) collectively across the entire span of the FSR 204. In other words, by adjusting the temperature of the tunable wavelength selection component 112, the controller 102 can move all transmission channels 202 together, maintaining their relative spacing defined by the FSR 204, and positioning the transmission channels 202 anywhere within the available frequency window set by the passband of the bandpass component 118. As a result, the second plurality of transmission channels 202 can be evenly distributed across any desired portion of the passband, offering flexible spectral alignment. This may be advantageous for applications such as WDM, such that the frequencies of the transmission channels 202 may be matched to the output channels of one or more predefined frequency grids, or for dynamic reconfiguration of multi-channel systems. Thus, the laser system 100 enables the generation of multiple, evenly spaced transmission channels 202, and the ability to position this set of transmission channels 202 at any location within the broader spectral region defined by the bandpass component 118, increasing operational versatility and compatibility with various optical networks.

As indicated above, FIG. 2 is provided as an example. Other examples may differ from what is shown in and described with regard to FIG. 2.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An apparatus, comprising:
a gain chip, within a cavity of the apparatus, configured to emit a light beam;
a tunable wavelength selection component, within the cavity, configured to filter the light beam into a first plurality of tunable transmission channels separated by a free spectral range; and
a bandpass component, within the cavity, configured to define a spectral bandpass that enables a second plurality of tunable transmission channels that form a multi-channel light beam for output from the cavity, wherein the second plurality of tunable transmission channels is a subset of the first plurality of tunable transmission channels that falls within the spectral bandpass.

2. The apparatus of claim 1, further comprising:
a heating component, attached to the tunable wavelength selection component and to the bandpass component, configured to apply heat to the tunable wavelength selection component and to the bandpass component;
a temperature sensor, attached to the tunable wavelength selection component and to the bandpass component, that is configured to monitor a temperature of the tunable wavelength selection component and the bandpass component; and
a controller, operatively coupled to the heating component and the temperature sensor, configured to adjust a plurality of wavelengths corresponding to the second plurality of tunable transmission channels based on adjusting a temperature output of the heating component.

3. The apparatus of claim 2, wherein the controller is operable to concurrently shift the second plurality of wavelengths across an optical spectrum.

4. The apparatus of claim 1, wherein the free spectral range defines a fixed channel spacing between the second plurality of tunable transmission channels.

5. The apparatus of claim 1, wherein the tunable wavelength selection component comprises an etalon filter.

6. The apparatus of claim 1, wherein a facet of the gain chip and a reflector, optically couplable to the gain chip, define the cavity of the apparatus.

7. The apparatus of claim 1, wherein the bandpass component is configured to allow the second plurality of tunable transmission channels to contain a defined number of tunable transmission channels.

8. The apparatus of claim 1, further comprising a first isolator component, a lens, and a fiber output, wherein:
the first isolator component is configured to prevent optical back-reflection into the cavity of the apparatus;
and the lens is configured to focus the multi-channel light beam into the fiber output.

9. The apparatus of claim 8, further comprising an optical amplifier and a second isolator component that are positioned between the first isolator component and the lens, wherein the optical amplifier is configured to increase an output power of the multi-channel light beam.

10. The apparatus of claim 1, further comprising:
a splitter component, inside or outside of the cavity, configured to reflect a portion of the multi-channel light beam;
a photodiode, inside or outside of the cavity, configured to receive the portion of the multi-channel light beam and generate a photodiode current value that is proportional to an output power of the multi-channel light beam; and
a controller, operatively coupled to the photodiode and one or more of the gain chip or an optical amplifier, configured to adjust one or more of a first current applied to the gain chip based on the photodiode current value or a second current applied to the optical amplifier based on the photodiode current value, wherein one or more of the first current or the second current controls the output power of the multi-channel light beam.

11. The apparatus of claim 1, further comprising:
a carrier; and
a thermoelectric cooler (TEC) attached to the carrier, wherein the gain chip and the tunable wavelength selection component are attached to the TEC.

12. The apparatus of claim 11, further comprising:
a thermistor, attached to the carrier, configured to indicate a temperature of the carrier; and
a controller, operatively coupled to the thermistor and the TEC, configured to apply a current to the TEC based on the temperature of carrier, wherein the TEC maintains the temperature of the carrier within a temperature range based on the current.

13. A laser system, comprising:
a gain chip, within a cavity of the laser system, configured to emit a light beam;
a tunable wavelength selection component, within the cavity, configured to filter the light beam into a first plurality of tunable transmission channels separated by a free spectral range; and
a bandpass component, within the cavity, configured to define a spectral bandpass that enables a second plurality of tunable transmission channels that form a multi-channel light beam for output from the cavity, wherein the second plurality of tunable transmission channels is a subset of the first plurality of tunable transmission channels that falls within the spectral bandpass.

14. The laser system of claim 13, further comprising:
a heating component, attached to the tunable wavelength selection component and to the bandpass component, configured to apply heat to the tunable wavelength selection component and to the bandpass component;
a temperature sensor, attached to the tunable wavelength selection component and to the bandpass component, that is configured to monitor a temperature of the tunable wavelength selection component and the bandpass component; and
a controller, operatively coupled to the heating component and the temperature sensor, configured to adjust a plurality of wavelengths corresponding to the second plurality of tunable transmission channels based on adjusting a temperature output of the heating component.

15. The laser system of claim 14, wherein the controller is operable to concurrently shift the second plurality of wavelengths across an optical spectrum.

16. The laser system of claim 13, wherein the free spectral range defines a fixed channel spacing between the second plurality of tunable transmission channels.

17. The laser system of claim 13, wherein the tunable wavelength selection component comprises an etalon filter.

18. The laser system of claim 13, wherein a facet of the gain chip and a reflector, optically couplable to the gain chip, define the cavity of the laser system.

19. The laser system of claim 13, wherein the bandpass component is configured to allow the second plurality of tunable transmission channels to contain a defined number of tunable transmission channels.

20. An external-cavity laser, comprising:
a gain chip, within a cavity of the external-cavity laser, configured to emit a light beam;
a tunable wavelength selection component, within the cavity, configured to filter the light beam into a first plurality of tunable transmission channels separated by a free spectral range; and
a bandpass component, within the cavity, configured to define a spectral bandpass that enables a second plurality of tunable transmission channels that form a multi-channel light beam for output from the cavity, wherein the second plurality of tunable transmission channels is a subset of the first plurality of tunable transmission channels that falls within the spectral bandpass.
